(19) United States
(12) Patent Application Publication
(10) Pub. No.: US 2026/0296204 A1
(43) Pub. Date: Oct. 1, 2026

(54) APPARATUS AND MEHTOD FOR CONTROLLING POWER SUPPLY

(71) Applicant: HL MANDO CORPORATION, Gyeonggi-do (KR)

(72) Inventor: Kwanseek KIM, Gyeonggi-do (KR)

(21) Appl. No.: 19/330,806

(22) Filed: Sep. 16, 2025

(30) Foreign Application Priority Data
Mar. 26, 2025 (KR) 10-2025-0038963

(51) Int. Cl. B60L 3/04; B60L 3/00; H02J 7/00; H02M 7/537; H03K 17/22

(52) U.S. Cl. CPC B60L 3/0046; H02J 7/84; H03K 17/302; B60L 3/003; B60L 3/04; B60L 50/40; H02J 2207/50

(57) ABSTRACT

The power supply control apparatus is provided. The power supply control apparatus includes: a switching module configured to connect a power supply unit of a vehicle and a capacitor bank configured to store power output from the power supply unit; and a controller configured to monitor a voltage of the capacitor bank and control an operation of the switching module based on a result of the monitoring, wherein the controller includes: a switching driver configured to output a switching control signal to control the operation of the switching module; an analog-to-digital converter configured to monitor the voltage of the capacitor bank; and a processor configured to determine a degradation state of the capacitor bank based on the monitoring result and control a duty ratio of the switching control signal based on the determined degradation state.

### CROSS REFERENCE TO PARENT APPLICATIONS

This application claims the benefit of Korean Patent Application No. 10-2025-0038963 filed on Mar. 26, 2025, in the Korean Intellectual Property Office, the disclosure of which is incorporated herein by reference.

### BACKGROUND

Various embodiments of the present disclosure generally relate to a power supply control apparatus and more particularly to a power supply control apparatus and method for a vehicle based on capacitor degradation monitoring.

In recent years, the adoption of large-capacity power conversion devices has been increasing in the automotive industry, particularly with the growing prevalence of eco-friendly vehicles such as electric vehicles. These power conversion devices typically include inverters and converters, which necessarily employ large-capacity electrolytic capacitors.

In particular, in vehicles such as electric vehicles, it is common practice to cut off power during parking to minimize the battery's standby current consumption. Consequently, upon restarting the vehicle, the large-capacity electrolytic capacitor must be recharged. In this situation, it is critically important to properly control the sudden surge of charging current, commonly referred to as inrush current, as it directly affects the service life of the capacitor.

Conventionally, to limit such inrush current, a power switching device has been used in conjunction with a separate electrical switch and a resistor. While this approach is advantageous in suppressing excessive current during capacitor charging, it suffers from a significant drawback in that the large series resistance results in a prolonged charging time until the electrolytic capacitor is fully charged.

However, such extended charging time does not meet the operational requirements of modern vehicles, which demand immediate system activation upon turning on the ignition (IGN). Therefore, there is a pressing need to develop a novel technique that can minimize the capacitor charging time while ensuring the long-term reliability and service life of the electrolytic capacitor.

### SUMMARY

The features and advantages of the present disclosure will be more readily understood and apparent from the following detailed description, which should be read in conjunction with the accompanying drawings, and from the claims which are appended to the end of the detailed description.

According to various embodiments of the present disclosure, a power supply control apparatus may comprise: a switching module configured to connect a power supply unit of a vehicle and a capacitor bank configured to store power output from the power supply unit; and a controller configured to monitor a voltage of the capacitor bank and control an operation of the switching module based on a result of the monitoring, wherein the controller may comprise: a switching driver configured to output a switching control signal to control the operation of the switching module; an analog-to-digital converter configured to monitor the voltage of the capacitor bank; and a processor configured to determine a degradation state of the capacitor bank based on the monitoring result and control a duty ratio of the switching control signal based on the determined degradation state.

The processor may be configured to identify the degradation state of the capacitor bank based on an increase in a time taken for the capacitor bank to reach a target voltage relative to a preset reference time when power is supplied from the power supply unit.

The switching module may comprise a first switching unit configured to control power supply from the power supply unit based on the switching control signal.

The switching module may further comprise a resistive voltage divider circuit configured to control a voltage of the switching control signal.

The resistive voltage divider circuit may comprise: a first resistor connected to a gate terminal of the first switching unit; and a second resistor and a second switching unit connected in parallel to the first resistor.

The resistive voltage divider circuit may be configured to to determine the gate voltage of the first switching unit based on a preset ratio when the second switching unit is turned on.

The processor may be configured to control the gate voltage by controlling operation of the second switching unit based on predetermined charging sections of the capacitor bank.

The processor may be configured to: turn on the second switching unit during a first charging section to reduce the gate voltage and adjust the voltage of the capacitor bank; and turn off the second switching unit during a second charging section to increase the gate voltage and adjust the voltage of the capacitor bank.

The first charging section may be defined as a section in which a charge level of the capacitor bank is less than a preset threshold, and the second charging section is defined as a section in which the charge level of the capacitor bank is equal to or greater than the preset threshold.

The processor may be configured to output a warning signal when the degradation state of the capacitor bank exceeds a reference value.

The power supply control apparatus may further comprise an inverter configured to convert the power output from the power supply unit and supply it to a motor provided in the vehicle. The processor may be configured to control the operation of the switching module to cut off power supply from the power supply unit when an abnormal condition is detected in the inverter.

According to some embodiments of the present disclosure, a method for controlling power supply by a power supply control apparatus provided in a vehicle may include: supplying power to a capacitor bank based on a switching control signal that controls an operation of a switching module disposed between a power supply unit and the capacitor bank; monitoring a voltage of the capacitor bank; identifying a degradation state of the capacitor bank based on a result of the monitoring; and controlling a duty ratio of the switching control signal based on the identified degradation state.

This Summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Various embodiments in accordance with the present disclosure will be described with reference to the drawings, in which:

FIG. 1 shows a schematic view of a vehicle including a power supply control apparatus according to one or more exemplary embodiments of the present disclosure.

FIG. 2 illustrates a circuit configuration of a vehicle including the power supply control apparatus according to one or more exemplary embodiments of the present disclosure.

FIG. 3 shows a detailed circuit diagram of a switching module of the power supply control apparatus according to one or more exemplary embodiments of the present disclosure.

FIG. 4 illustrates a graph illustrating a method for monitoring the degradation state of a capacitor bank according to one or more exemplary embodiments of the present disclosure.

FIG. 5 illustrates a timing diagram illustrating a method for controlling the switching module based on charging sections of the capacitor bank according to an embodiment of the present disclosure.

FIG. 6 shows a flowchart illustrating a power supply control method according to one or more exemplary embodiments of the present disclosure.

FIG. 7 shows a flowchart illustrating a control method based on charging sections in the power supply control method according to one or more exemplary embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF EMBODIMENTS

In the following detailed description, reference is made to the accompanying drawings which form a part of the present disclosure, and in which are shown by way of illustration specific embodiments in which the invention may be practiced. These embodiments are described in sufficient detail to enable those skilled in the art to practice the invention, and it is to be understood that other embodiments may be utilized and that structural, logical and electrical changes may be made without departing from the spirit and scope of the invention. The following detailed description is therefore not to be taken in a limiting sense, and the scope of the invention is defined only by the appended claims and equivalents thereof. Like numbers in the figures refer to like components, which should be apparent from the context of use.

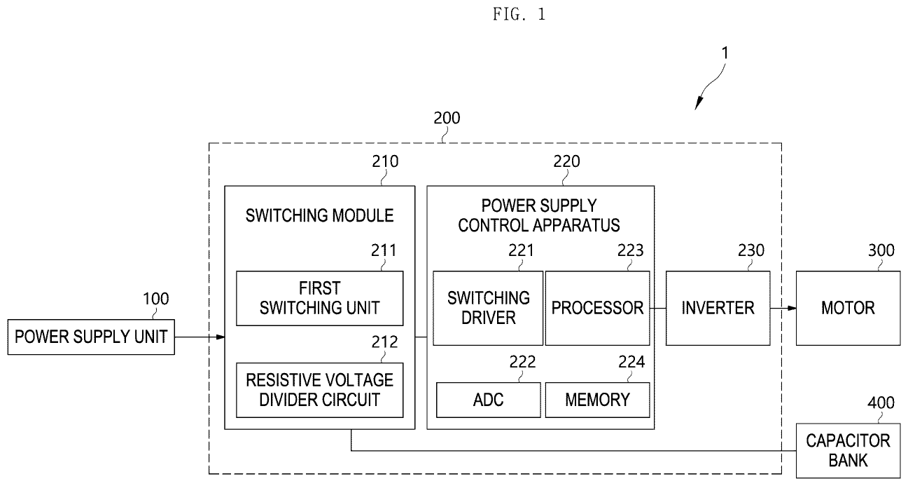

Referring to FIG. 1, a vehicle 1 according to one or more exemplary embodiments of the present disclosure may include a power supply unit 100, a power supply control apparatus 200, a motor 300, and a capacitor bank 400.

The power supply unit 100 may include a battery configured to provide power required to drive the vehicle 1. For example, the power supply unit 100 may include a battery that outputs a voltage of approximately 12V or higher. However, the configuration of the power supply unit 100 is not limited thereto.

The power supply control apparatus 200 may supply the power output from the power supply unit 100 to at least one of the motor 300 and the capacitor bank 400. The power supply control apparatus 200 may include a switching module 210, a controller 220, and an inverter 230.

The switching module 210 may be disposed between the power supply unit 100 and the capacitor bank 400 and may control power supply therebetween. Specifically, the switching module 210 may perform a pre-charging function to limit an initial inrush current flowing into the capacitor bank 400 under control of the controller 220, and may also perform a fail-safe function to cut off power supply when an abnormality occurs in the inverter 230.

The controller 220 may monitor the voltage of the capacitor bank 400 and control the operation of the switching module 210 based on the monitoring result. The controller 220 may include a switching driver 221, an analog-to-digital converter (ADC) 222, a processor 223, and a memory 224.

The switching driver 221 may output a switching control signal to control the operation of the switching module 210 under the control of the processor 223. The switching control signal may be generated using a pulse width modulation (PWM) scheme and may be configured to activate the switching module 210 to either turn on or turn off. Depending on the resolution, the switching control signal may allow current to flow freely between the power supply unit 100 and at least one of the motor 300 and the capacitor bank 400. In this manner, the switching driver 221 may control the operation of the switching module 210 so that the power from the power supply unit 100 is delivered to at least one of the motor 300 and the capacitor bank 400.

The analog-to-digital converter 222 may continuously monitor the voltage of the capacitor bank 400 in real time, convert the monitored voltage into a digital signal, and transmit it to the processor 223.

The processor 223 may be implemented as one or more processors included in the controller 220. The processor 223 may generate a PWM pattern for turning the switching module 210 on and off. Additionally, the processor 223 may calculate an increase in the time it takes for the capacitor bank 400 to reach a target voltage compared to a preset reference time when power is supplied from the power supply unit 100, and may identify a degradation state of the capacitor bank 400 based on the calculated increase. Further description of the processor 223 is provided below.

The memory 224 may also be included in the controller 220 and may store programs and data for performing operations of the components included in the power supply control apparatus 200. For example, the memory 224 may store an initial charge time reference value of the capacitor bank 400, a PWM duty ratio mapping table corresponding to different degradation states, threshold values for detecting current imbalance in the inverter 230, system operation history and fault records of the vehicle 1, and voltage and current thresholds for various protection functions. These data may be periodically updated to reflect the status changes of the system and may be used to analyze degradation progression of the capacitor bank 400.

The memory 224 may provide stored programs and data to the processor 223 and temporarily store data generated during the operation of the processor 223. For instance, the memory 224 may include volatile memories such as static RAM (S-RAM) and dynamic RAM (D-RAM), and non-volatile memories such as read-only memory (ROM), erasable programmable ROM (EPROM), and flash memory.

The motor 300 may receive power via the inverter 230 of the power supply control apparatus 200 and convert the power to generate driving force for the vehicle 1. The motor 300 may be implemented as a three-phase permanent magnet synchronous motor (PMSM) or an induction motor, for example.

The motor 300 may be driven by converting direct current (DC) power supplied from the capacitor bank 400 into three-phase alternating current (AC) power through the inverter 230. The motor 300, as a key component for determining the vehicle's speed, torque, and energy efficiency, may deliver stable and efficient performance based on precise power control by the power supply control apparatus 200.

The capacitor bank 400, acting as a high-capacity load, may be implemented as a DC link capacitor configured to temporarily store power output from the power supply unit 100. The capacitor bank 400 may include a plurality of electrolytic capacitors and may supply power necessary for the stable operation of the inverter 230.

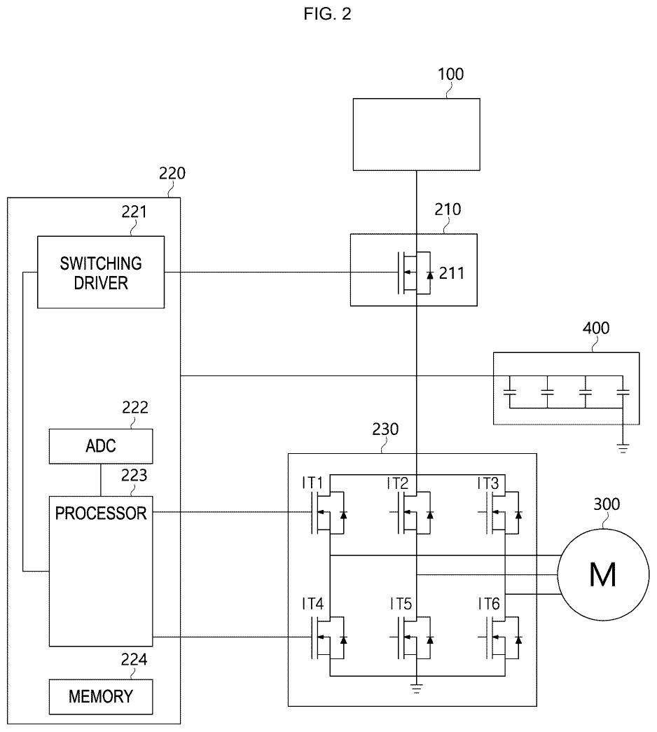

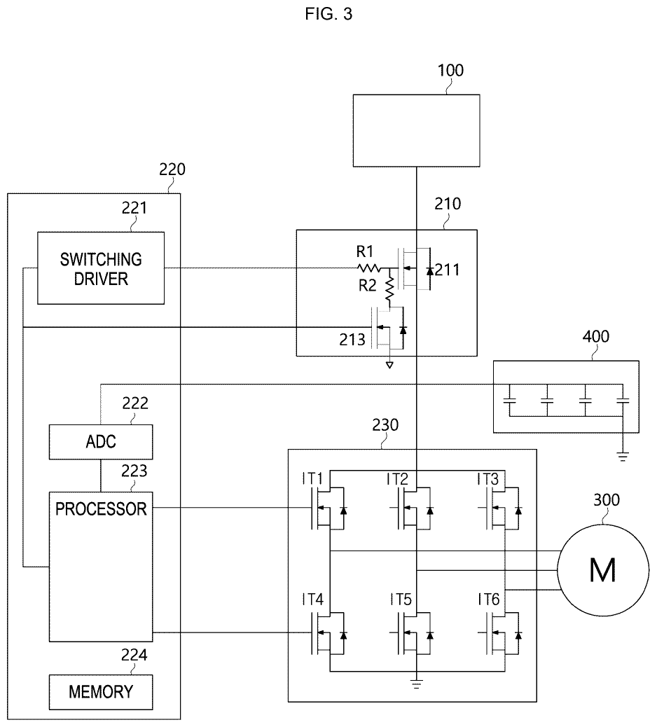

Referring to FIGS. 2 and 3, the switching module 210 may include a first switching unit 211 and a resistive voltage divider circuit 212.

The first switching unit 211 may control an electrical connection between the power supply unit 100 and the capacitor bank 400 in response to a switching control signal. In one or more exemplary embodiments, the first switching unit 211 may be implemented using various types of power semiconductor devices.

The first switching unit 211 may include at least one of a high-voltage field-effect transistor (FET), insulated gate bipolar transistor (IGBT), silicon controlled rectifier (SCR), gate turn-off thyristor (GTO), MOS-controlled thyristor (MCT), super-junction MOSFET (SJ-MOSFET), or silicon carbide (SiC) MOSFET.

For example, the first switching unit 211 may be implemented using a SiC MOSFET. The SiC MOSFET offers advantages such as reduced switching losses due to its low on-resistance and high-speed switching characteristics. Additionally, due to its high breakdown voltage characteristics, the SiC MOSFET may operate reliably in high-voltage systems of approximately 48V or higher.

A gate drive circuit of the first switching unit 211 may turn the first switching unit 211 on or off based on the switching control signal provided by the switching driver 221. In this regard, the gate resistance of the gate drive circuit may be appropriately selected to limit sharp di/dt transitions during switching events. A ceramic capacitor with a capacitance of approximately 0.1 μF may be connected in parallel between the gate and source terminals as a bypass capacitor to reduce noise. A protection circuit employing a Zener diode may be configured to protect the gate terminal from overvoltage. Moreover, a Miller clamp circuit may be provided to secure an active turn-off path and prevent parasitic turn-on.

The resistive voltage divider circuit 212 may include a first resistor R1 connected to the gate terminal of the first switching unit 211, and a second resistor R2 and a second switching unit 213 connected in parallel with the first resistor R1. The first resistor R1 and the second resistor R2 may have the same resistance value. The second switching unit 213 may include a small-signal FET suitable for handling low currents.

However, the configuration of the resistive voltage divider circuit 212 is not limited to the above. For example, the ratio between the resistance values of R1 and R2 may be adjusted to control the degree of voltage drop at the gate terminal. Additionally, a multi-stage (e.g., three or more) resistive voltage divider circuit 212 may be implemented to enable more precise control of the gate voltage.

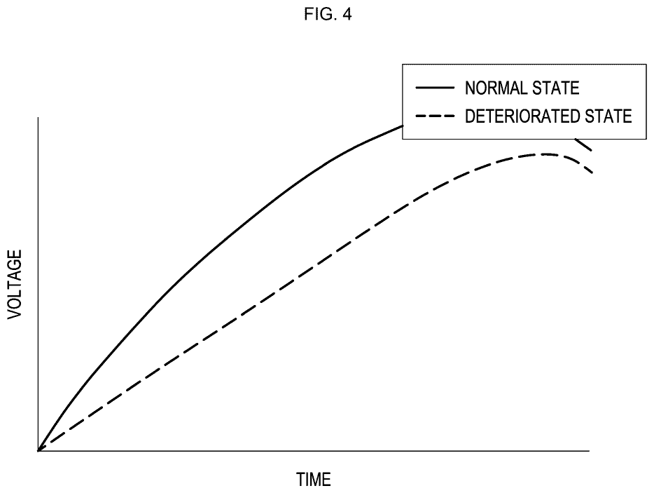

Referring to FIG. 4, a method for monitoring a degradation state of the capacitor bank 400 is illustrated.

In FIG. 4, the horizontal axis represents time, and the vertical axis represents the voltage of the capacitor bank 400. A solid line (A) indicates a charging curve of the capacitor bank 400 in an initial (non-degraded) state, while a dashed line (B) indicates a charging curve of the capacitor bank 400 in a degraded state.

The processor 223 may measure a time taken for the voltage of the capacitor bank 400 to reach a target voltage (e.g., 90% of the battery voltage) when power is supplied from the power supply unit 100. If the measured time increases by a certain threshold ratio (e.g., 10%) compared to a preset reference time, the processor 223 may identify that the capacitor bank 400 is in a degraded state.

The processor 223 may control the operation of the second switching unit 213 according to the charging sections of the capacitor bank 400 in order to adjust the gate voltage of the first switching unit 211.

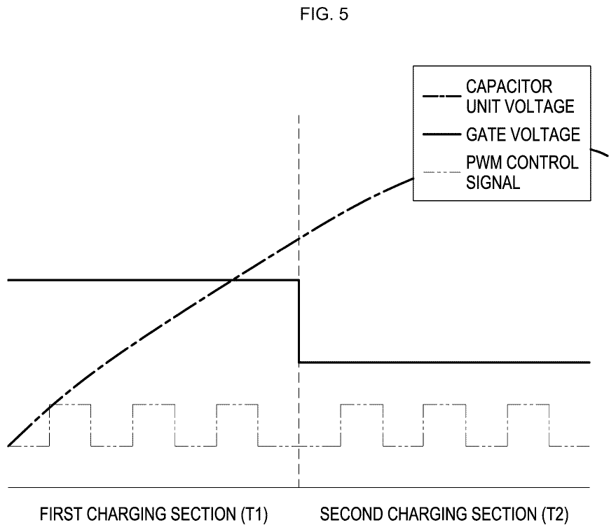

Referring to FIG. 5, the charging process of the capacitor bank 400 may be divided into a first charging section (T1) and a second charging section (T2).

The first charging section T1 may be defined as an initial charging period in which the amount of charge in the capacitor bank 400 is less than a predetermined charge threshold (e.g., approximately 50%).

In the first charging section T1, the processor 223 may employ a dual control scheme combining hardware-based and software-based control methods to effectively limit an initial inrush current flowing into the capacitor bank 400 and control the switching module 210 accordingly.

In the hardware-based control method, the processor 223 may control the gate voltage using the resistive voltage divider circuit 212. Specifically, the processor 223 may turn on the second switching unit 213 during the first charging section T1. When the second switching unit 213 is turned on, the voltage applied to the gate terminal of the first switching unit 211 may be reduced due to the voltage division by the first and second resistors R1 and R2.

The first resistor R1 and the second resistor R2 may be configured to have the same resistance value (e.g., 10 kΩ), so that the gate voltage is reduced to approximately half of the input voltage. This reduction in gate voltage may decrease the conduction rate of the first switching unit 211, thereby limiting the inrush current through hardware control.

In the software-based control method, the processor 223 may control the duty ratio of the switching control signal. For example, during the first charging section T1, the processor 223 may control the switching driver 221 to generate a PWM signal with a duty ratio of approximately 30% or less. Such a low-duty PWM control may limit the average current supplied to the capacitor bank 400 by controlling the on/off time of the first switching unit 211.

Through this dual control approach, which combines gate voltage control and PWM duty ratio control, the power supply control apparatus 200 according to an embodiment of the present disclosure may more reliably and effectively limit the inrush current, even in high-voltage battery systems of 48V or higher. In particular, the complementary interaction between the hardware and software control mechanisms may enhance the reliability of current limitation.

The second charging section T2 may be defined as a later charging period in which the charge level of the capacitor bank 400 reaches or exceeds the predetermined threshold (e.g., 50%). In the second charging section T2, since the risk of inrush current decreases, the processor 223 may switch the second switching unit 213 to an OFF state. As a result, the gate voltage of the first switching unit 211 may return to a normal level, thereby increasing conduction efficiency.

When the second switching unit 213 is turned off, no voltage drop occurs across the resistive voltage divider circuit 212, and the output voltage of the switching driver 221 may be directly applied to the gate terminal of the first switching unit 211.

The processor 223 may also adaptively control the PWM duty ratio based on the degradation state of the capacitor bank 400. In particular, as the degradation of the capacitor bank 400 progresses, the processor 223 may gradually reduce the PWM duty ratio to limit the charging current.

In embodiments, the processor 223 may set the PWM frequency to approximately 20 kHz to avoid the audible frequency range while maintaining appropriate switching efficiency. Furthermore, the processor 223 may adjust the PWM duty ratio according to both the charging section and the degradation state of the capacitor bank 400. In the first charging section T1, the duty ratio may be limited to 30% or less to restrict the inrush current.

The processor 223 may also measure the charging time of the capacitor bank 400 when power is supplied from the power supply unit 100, and determine and classify the degradation state based on a difference between the measured time and a reference charging time.

For example, when the increase in charging time is less than approximately 10%, the capacitor bank 400 may be identified as being in a normal (non-degraded) state, and the processor 223 may maintain the duty ratio of the switching control signal at approximately 70% to 90%. If the charging time increase is between approximately 10% and 20%, indicating a first-level degradation (initial degradation), the processor 223 may reduce the duty ratio to around 70%. If the increase is between 20% and 30%, indicating a second-level degradation (progressive degradation), the duty ratio may be reduced to about 50%. When the charging time increases by 30% or more, indicating a third-level degradation (severe degradation), the processor 223 may further reduce the duty ratio to 30% or less and output a warning signal.

Referring again to FIG. 2, the power supply control apparatus 200 may drive the motor 300 through the inverter 230. Additionally, the power supply control apparatus 200 may detect an abnormality of the inverter 230 and perform a fail-safe function to ensure safe operation of the vehicle 1.

The inverter 230 may be configured as a three-phase inverter including six inverter switches IT1 to IT6. The inverter 230 may convert direct current (DC) power supplied from the capacitor bank 400 into three-phase alternating current (AC) power to drive the motor 300.

Each of the plurality of inverter switches IT1 to IT6 may perform on/off operations in response to control signals from the processor 223 to execute power conversion. Each of the inverter switches IT1 to IT6 may receive a pulse width modulation (PWM)-based inverter switching control signal to perform switching operations. In this context, the processor 223 may supply respective inverter switching control signals to the gate electrodes of the inverter switches IT1 to IT6.

In embodiments, the processor 223 may supply a first PWM-based inverter switching control signal to the gate electrode of the first inverter switch IT1, a second PWM-based inverter switching control signal to the gate electrode of the second inverter switch IT2, a third PWM-based inverter switching control signal to the gate electrode of the third inverter switch IT3, a fourth PWM-based inverter switching control signal to the gate electrode of the fourth inverter switch IT4, a fifth PWM-based inverter switching control signal to the gate electrode of the fifth inverter switch IT5, and a sixth PWM-based inverter switching control signal to the gate electrode of the sixth inverter switch IT6.

If any one of the inverter switches IT1 to IT6 malfunctions, the balance of the three-phase AC may be disrupted, which may cause the motor 300 to operate abnormally. Such abnormal operation may result in severe damage to the overall vehicle 1 system. Accordingly, the processor 223 may monitor the operational status of the inverter 230 in real time to detect any abnormality.

Specifically, the processor 223 may detect the current flowing through each of the three phases (U-phase, V-phase, and W-phase) of the inverter 230 and determine whether there is current imbalance among the phases. Under normal operating conditions, the three-phase currents flow with a phase difference of approximately 120 degrees and with uniform magnitude. However, if at least one of the inverter switches IT1 to IT6 malfunctions, the current of a particular phase may abnormally increase or decrease.

For example, if the current of one phase differs by approximately 20% or more from that of the other phases, or if the phase difference deviates from approximately 120±10 degrees, the processor 223 may determine that an abnormality has occurred in the inverter 230.

In addition, the processor 223 may receive feedback on the on/off states of each of the inverter switches IT1 to IT6 and verify whether normal switching operations are being performed in accordance with the control signals. The processor 223 may also monitor whether the temperature of the inverter 230 exceeds a predetermined threshold using a temperature sensor installed in the inverter 230.

When the processor 223 detects an abnormal condition in the inverter 230 during such monitoring processes, it may perform immediate response actions. First, the processor 223 may control the switching driver 221 to turn off the first switching unit 211, thereby cutting off power supply from the power supply unit 100 to the capacitor bank 400. This prevents further power delivery and minimizes potential damage to the vehicle 1.

Furthermore, the processor 223 may stop the operation of the inverter 230 to shut down the motor 300 and output a warning signal to alert the driver of the detected abnormality.

The power supply control apparatus 200 according to one or more exemplary embodiments of the present disclosure may perform various fault detection and response functions.

The controller 220 of the power supply control apparatus 200 may detect an overvoltage condition of the capacitor bank 400. The processor 223 may continuously monitor the voltage of the capacitor bank 400 via the analog-to-digital converter 222 and determine the occurrence of an overvoltage state if the measured voltage exceeds a preset upper threshold.

Upon detecting an overvoltage condition, the processor 223 may immediately turn off the first switching unit 211 to cut off the power supply and wait until the voltage of the capacitor bank 400 decreases to within a safe range.

In embodiments, if the voltage of the capacitor bank 400 exceeds approximately 110% of its rated voltage, the analog-to-digital converter 222 may determine it as an overvoltage condition and notify the processor 223 of the result.

Additionally, the processor 223 may protect at least one of the power supply control apparatus 200, the motor 300, and the capacitor bank 400 by detecting an undervoltage condition when the voltage of the power supply unit 100 falls below a predetermined lower threshold.

The power supply control apparatus 200 may detect performance degradation caused by the deterioration of the capacitor bank 400. As described above, the processor 223 may determine the degradation state based on an increase in the charging time, and if a severe degradation is detected, may output a warning signal to notify the driver that maintenance of the vehicle 1 is required.

The power supply control apparatus 200 may detect abnormal operation of the inverter 230. When a current imbalance in the three-phase system, a malfunction of a switching element, or overheating is detected, the power supply control apparatus 200 may execute sequential protection actions.

Specifically, upon detecting an abnormality of the inverter 230, the processor 223 may immediately switch off the plurality of inverter switches IT1 to IT6 to cut off the power supply to the motor 300. Then, the processor 223 may control the switching driver 221 to turn off the first switching unit 211, thereby cutting off power supply from the power supply unit 100.

The power supply control apparatus 200 according to one or more exemplary embodiments of the present disclosure may utilize the degradation state identification result of the capacitor bank 400 to establish a preventive maintenance schedule for the vehicle 1. The processor 223 may analyze the progression rate of deterioration of the capacitor bank 400 and estimate the appropriate timing for future maintenance.

The degradation monitoring function of the power supply control apparatus 200 may also be utilized for planning preventive maintenance of the vehicle. The processor 223 may analyze a degradation progression rate of the capacitor bank 400 to estimate a future maintenance timing. For example, the processor 223 may calculate a degradation trend based on charging time data collected from the most recent ten charging cycles and determine an estimated time when the capacitor bank 400 is expected to reach a severe degradation state.

Such information may be provided to a driver or a maintenance service center so that preventive maintenance can be performed at an appropriate time. Specifically, the processor 223 may analyze the degradation trend using recent charging data (e.g., charging time records of the latest ten cycles), calculate the projected point of severe degradation, and provide a corresponding maintenance recommendation. The processor 223 may also notify the driver based on the predicted timing so that maintenance can be scheduled in advance.

In one or more exemplary embodiments of the present disclosure, the power supply control apparatus 200 may effectively limit the inrush current during initial charging using a dual control strategy that combines hardware-based and software-based current limiting methods. In particular, stable charging may be achieved even in high-voltage battery systems of approximately 48V or higher. The gate voltage control through the resistive voltage divider circuit 212 may provide hardware-level current limiting, and the PWM duty ratio control may provide software-level current limiting. This dual control strategy may offer more stable and reliable current limitation compared to a single control scheme.

Additionally, the power supply control apparatus 200 may monitor the degradation state of the capacitor bank 400 in real time and adaptively control the charging current in response to the degradation state, thereby extending the life of the capacitor. In particular, the processor 223 may delay the progression of degradation by gradually adjusting the PWM duty ratio according to the degree of degradation and may issue a warning signal in advance of severe degradation to enable preventive maintenance.

Furthermore, in one or more exemplary embodiments of the present disclosure, the power supply control apparatus 200 may implement both the pre-charging function and the fail-safe function using a single first switching unit 211. During pre-charging, the gate voltage control and PWM duty ratio control may limit the initial charging current, and when an abnormal condition occurs in the inverter 230, the power supply may be cut off to protect the system. By implementing both functions with a single switching device, the number of components may be reduced and the system configuration may be simplified.

Moreover, the power supply control apparatus 200 may divide the charging process into a first charging section and a second charging section, and apply an optimized control strategy for each section to ensure both safety and efficiency. During the initial charging period, enhanced current limiting may ensure safety, while in the later charging stage, adaptive control based on the degradation state may improve efficiency.

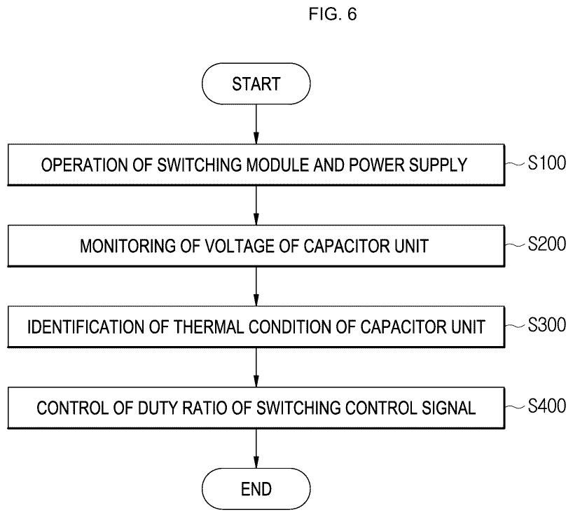

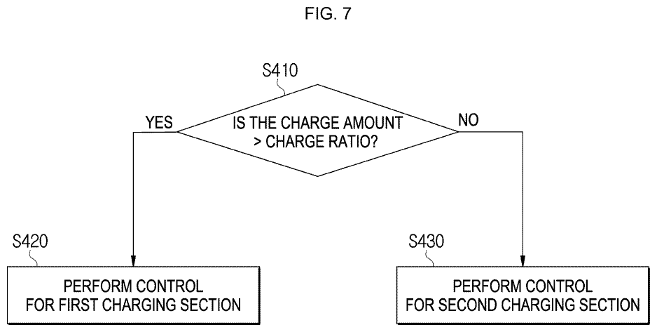

Hereinafter, a power supply control method according to one or more exemplary embodiments of the present disclosure will be described with reference to FIGS. 6 and 7.

FIG. 6 is a flowchart illustrating a power supply control method, and FIG. 7 is a flowchart illustrating a charging-section-based control method according to an exemplary embodiment of the present disclosure.

The following description relates to a power supply control method performed by the power supply control apparatus described with reference to FIGS. 1 to 5.

Referring to FIGS. 6 and 7, when the vehicle 1 is turned on, the processor 223 may control the operation of the switching module 210 disposed between the power supply unit 100 and the capacitor bank 400 to supply power to the capacitor bank 400 (S100).

The switching module 210, which includes the first switching unit 211 and the resistive voltage divider circuit 212, may control an electrical connection between the power supply unit 100 and the capacitor bank 400 based on a switching control signal. The first switching unit 211 may include at least one of a high-voltage field-effect transistor (FET), insulated gate bipolar transistor (IGBT), silicon controlled rectifier (SCR), gate turn-off thyristor (GTO), MOS-controlled thyristor (MCT), super-junction MOSFET (SJ-MOSFET), or silicon carbide (SiC) MOSFET.

The first switching unit 211 may be switched on or off based on a gate voltage supplied to its gate electrode. The switching driver 221, which outputs the switching control signal to the first switching unit 211, may control the operation of the switching module 210 under control of the processor 223. The switching control signal may be a PWM (pulse-width modulation) signal and may enable or disable the switching module 210 to allow current to flow freely between the power supply unit 100 and at least one of the motor 300 and the capacitor bank 400, depending on the resolution. In this manner, the switching driver 221 may control the operation of the switching module 210 so that power from the power supply unit 100 is delivered to at least one of the motor 300 and the capacitor bank 400.

Next, the controller 220 may monitor the voltage of the capacitor bank 400 via the analog-to-digital converter 222 (S200).

Specifically, the analog-to-digital converter 222 may continuously monitor the voltage of the capacitor bank 400 in real time, convert it into a digital signal, and transmit it to the processor 223. To ensure accurate monitoring, the analog-to-digital converter 222 may include a voltage detection circuit. For example, the voltage detection circuit may be configured by connecting a 100 kΩ resistor on the high-voltage side and a 10 kΩ resistor on the low-voltage side in series. Each resistor may be selected to have a precision of approximately 0.1% and a temperature coefficient of approximately 25 ppm/° C. This voltage division ratio allows the input range to be optimized for accurate voltage monitoring.

In addition, the analog-to-digital converter 222 may include a low-pass filter configured with a cutoff frequency of approximately 10 kHz to remove high-frequency noise from the voltage detection circuit. To further prevent electromagnetic interference, shielded cables may be used, and the high-voltage and signal circuits may be physically separated on the PCB layout.

Voltage measurement by the analog-to-digital converter 222 may be performed as follows. The sampling frequency of the converter may be set to at least ten times the PWM frequency to sufficiently capture voltage fluctuations. The measured digital value may be processed using a moving average filter to remove instantaneous noise, and the filtered data may be used by the processor 223 to determine the charging status and degradation state of the capacitor bank 400. Such a configuration enables the power supply control apparatus 200 to perform more stable and precise control and improves noise immunity.

Based on the monitoring results, the processor 223 may identify the degradation state of the capacitor bank 400 (S300). In particular, the processor 223 may measure the time required for the capacitor bank 400 to reach a target voltage and compare it with a preset reference time. The processor 223 may calculate the increase in charging time relative to the reference time when power is supplied from the power supply unit 100 and determine the degradation state based on this increase. For example, if the measured time increases by more than a predetermined threshold ratio (e.g., 10%), the processor 223 may determine that the capacitor bank 400 has entered a degraded state.

The processor 223 may then control the operation of the switching module 210 based on the monitoring results. In particular, the processor 223 may control the duty ratio of the switching control signal depending on both the degradation state and the charging section of the capacitor bank 400 (S400).

According to one embodiment, different control strategies may be applied based on the charging amount of the capacitor bank 400. First, the processor 223 may compare the current charge level with a preset charge threshold (e.g., 50%) to distinguish between charging sections (S410).

If the charge level is below the preset threshold, indicating the first charging section (T1), the processor 223 may perform enhanced control to limit the inrush current (S420). The processor 223 may turn on the second switching unit 213 to reduce the gate voltage of the first switching unit 211 to approximately half of its normal level. At the same time, the duty ratio of the switching control signal may be limited to 30% or less. Through this dual control scheme, the processor 223 may effectively suppress the inrush current during initial charging, even in high-voltage systems of 48V or higher.

If the charge level exceeds the preset threshold, the charging process may enter the second charging section (T2) (S430). In this section, since the risk of inrush current is lower, the processor 223 may turn off the second switching unit 213 to return the gate voltage of the first switching unit 211 to its normal level. The duty ratio may then be adaptively adjusted based on the degradation state of the capacitor bank 400.

For example, if no degradation is detected, the duty ratio of the switching control signal may be maintained at approximately 70% to 90%. If the charging time increases by about 10%, indicating an early-stage degradation, the duty ratio may be reduced to around 70%. If the charging time increases by about 20%, indicating progressive degradation, the duty ratio may be reduced to around 50%. If the charging time increases by 30% or more, indicating severe degradation, the duty ratio may be reduced to 30% or less, and a warning signal may be output.

According to the power supply control method of the present disclosure, degradation progression of the capacitor bank 400 may be delayed and its lifespan extended by adaptive duty ratio control, while also enabling stable system operation.

Although the example embodiments have been described in detail, it should be understood that various changes, substitutions and alterations can be made herein without departing from the spirit and scope of the present disclosure as defined by the appended claims.

Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods or steps, presently existing or later to be developed, that perform substantially the same function or achieve substantially the same result as the corresponding embodiments described herein may be utilized according to the embodiments and alternative embodiments. Accordingly, the appended claims are intended to include within their scope such processes, machines, manufacture, compositions of matter, means, methods, or steps.

The explanations and illustrations presented herein are intended to acquaint others skilled in the art with the invention, its principles, and its practical application. The above description is intended to be illustrative and not restrictive. Those skilled in the art may adapt and apply the invention in its numerous forms, as may be best suited to the requirements of a particular use.

Accordingly, the specific embodiments of the present invention as set forth are not intended as being exhaustive or limiting of the teachings. The scope of the teachings should, therefore, be determined not with reference to this description, but should instead be determined with reference to the appended claims, along with the full scope of equivalents to which such claims are entitled. The omission in the following claims of any aspect of subject matter that is disclosed herein is not a disclaimer of such subject matter, nor should it be regarded that the inventors did not consider such subject matter to be part of the disclosed inventive subject matter.

Plural elements or steps can be provided by a single integrated element or step. Alternatively, a single element or step might be divided into separate plural elements or steps.

The disclosure of “a” or “one” to describe an element or step is not intended to foreclose additional elements or steps.

While the terms first, second, third, etc., may be used herein to describe various elements, components, regions, layers and/or sections, these elements, components, regions, layers and/or sections should not be limited by these terms. These terms may be used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

What is claimed is:

1. A power supply control apparatus comprising:
a switching module configured to connect a power supply unit of a vehicle and a capacitor bank configured to store power output from the power supply unit;
and a controller configured to monitor a voltage of the capacitor bank and control an operation of the switching module based on a result of the monitoring,
wherein the controller comprises:
a switching driver configured to output a switching control signal for controlling the operation of the switching module;
an analog-to-digital converter configured to monitor the voltage of the capacitor bank; and
a processor configured to identify a degradation state of the capacitor bank based on the result of the monitoring, and to control a duty ratio of the switching control signal based on the degradation state.

2. The power supply control apparatus of claim 1, wherein the processor is configured to identify the degradation state of the capacitor bank based on an increase in a time taken for the capacitor bank to reach a target voltage relative to a preset reference time when power is supplied from the power supply unit.

3. The power supply control apparatus of claim 1, wherein the switching module comprises a first switching unit configured to control power supply from the power supply unit based on the switching control signal.

4. The power supply control apparatus of claim 3, wherein the switching module further comprises a resistive voltage divider circuit configured to control a voltage of the switching control signal.

5. The power supply control apparatus of claim 4, wherein the resistive voltage divider circuit comprises:
a first resistor connected to a gate terminal of the first switching unit; and
a second resistor and a second switching unit connected in parallel with the first resistor.

6. The power supply control apparatus of claim 5, wherein the resistive voltage divider circuit is configured to determine the gate voltage of the first switching unit based on a preset ratio when the second switching unit is turned on.

7. The power supply control apparatus of claim 6, wherein the processor is configured to control the gate voltage by controlling operation of the second switching unit based on predetermined charging sections of the capacitor bank.

8. The power supply control apparatus of claim 7, wherein the processor is configured to:
turn on the second switching unit during a first charging section to reduce the gate voltage and adjust the voltage of the capacitor bank; and
turn off the second switching unit during a second charging section to increase the gate voltage and adjust the voltage of the capacitor bank.

9. The power supply control apparatus of claim 8, wherein the first charging section is defined as a section in which a charge level of the capacitor bank is less than a preset threshold, and the second charging section is defined as a section in which the charge level of the capacitor bank is equal to or greater than the preset threshold.

10. The power supply control apparatus of claim 3, wherein the processor is configured to output a warning signal when the degradation state of the capacitor bank exceeds a reference value.

11. The power supply control apparatus of claim 1, further comprising an inverter configured to convert power output from the power supply unit and supply the converted power to a motor provided in the vehicle, and wherein the processor is configured to control the operation of the switching module to cut off the power supply from the power supply unit when an abnormal condition is detected in the inverter.

12. A method of controlling power supply in a power supply control apparatus provided in a vehicle, the method comprising:
outputting a switching control signal to control an operation of a switching module provided between a power supply unit and a capacitor bank to supply power to the capacitor bank;
monitoring a voltage of the capacitor bank;
identifying a degradation state of the capacitor bank based on a result of the monitoring; and
controlling a duty ratio of the switching control signal based on the degradation state of the capacitor bank.

13. The method of claim 12, wherein identifying the degradation state comprises:
calculating an increase in a time taken for the capacitor bank to reach a target voltage relative to a preset reference time when power is supplied from the power supply unit, and
identifying the degradation state based on the calculated increase.

14. The method of claim 12, wherein the switching module comprises a first switching unit configured to control power supply from the power supply unit based on the switching control signal, and a resistive voltage divider circuit configured to control a voltage of the switching control signal, wherein the resistive voltage divider circuit comprises:
a first resistor connected to a gate terminal of the first switching unit; and
a second resistor and a second switching unit connected in parallel with the first resistor,
and wherein the controlling the duty ratio comprises controlling an operation of the second switching unit to control a gate voltage of the first switching unit.

15. The method of claim 14, wherein the controlling the gate voltage comprises controlling an operation of the second switching unit based on predefined charging sections of the capacitor bank.

16. The method of claim 15, wherein the controlling the gate voltage comprises:
turning on the second switching unit in a first charging section to reduce the gate voltage;
turning off the second switching unit in a second charging section to increase the gate voltage,
wherein the first charging section is defined as a section in which a charge level of the capacitor bank is less than a preset threshold, and the second charging section is defined as a section in which the charge level of the capacitor bank is equal to or greater than the preset threshold.

17. The method of claim 14, wherein the controlling the gate voltage comprises reducing the gate voltage of the first switching unit based on a preset ratio when the second switching unit is turned on.

18. The method of claim 14, wherein controlling the gate voltage comprises controlling power supplied to the capacitor bank by combining duty ratio control of the switching control signal and gate voltage control.

19. The method of claim 12, further comprising:
outputting a warning signal when the degradation state of the capacitor bank exceeds a reference value.

20. The method of claim 12, further comprising:
identifying an abnormality of an inverter configured to convert power output from the power supply unit and supply the converted power to a motor provided in the vehicle; and
controlling an operation of the switching module to cut off power supply from the power supply unit when the abnormality of the inverter is identified.
